(19) United States
(12) Patent Application Publication
(10) Pub. No.: US 2015/0009747 A1
(43) Pub. Date: Jan. 8, 2015

(54) PHASE SWITCHABLE BISTABLE MEMORY DEVICE, A FREQUENCY DIVIDER AND A RADIO FREQUENCY TRANSCEIVER

(71) Applicants: Akbar Ghazinour, Ottobrunn (DE); Saverio Trotta, Munich (DE)

(72) Inventors: Akbar Ghazinour, Ottobrunn (DE); Saverio Trotta, Munich (DE)

(21) Appl. No.: 13/933,527

(22) Filed: Jul. 2, 2013

(51) Int. Cl. G11C 11/41

(52) U.S. Cl. CPC G11C 11/41
USPC 365/154

(57) ABSTRACT

A phase switchable bistable memory device comprising a bistable memory component and a phase switching component is described. The bistable memory component comprises a bistable memory stage arranged to receive an input signal and a state transition stage arranged to receive a state transition signal and to cause the bistable memory stage to capture a logical state of the received input signal upon a transition from a first logical state of the state transition signal to a second logical state of the state transition signal. The phase switching component is arranged to receive a clock input signal and a phase control signal, and to output the state transition signal comprising transitions between logical states corresponding to transitions between logical states of the clock input signal and comprising a phase relative to the clock input signal based at least partly on the received phase control signal.

### FIELD OF THE INVENTION

The field of this invention relates to a phase switchable bistable memory device, a frequency divider and a radio frequency transceiver comprising the phase switchable bistable memory device, and in particular to a phase switchable bistable memory device for use within a low voltage frequency divider.

### BACKGROUND OF THE INVENTION

In the field of radio frequency (RF) transceivers, it is known to use a local oscillator (LO) to provide mixing frequency signals to up-convert low frequency modulated signals for transmission within the transmit path and/or to down-convert received signals for demodulation in the receive path. On-channel LO frequencies can interact with and corrupt received and transmitted signals. Accordingly, it is known to use off-channel LOs, and to perform division and/or multiplication of the LO frequency signal to generate the required mixing frequency. A typical LO path may comprise an odd order frequency division of the LO signal followed by an even order multiplication of the divided LO signal. In particular, in a typical quad-band GSM (Global System for Mobile communication) transceiver, an LO path may comprise a divide-by-three frequency division followed by an even multiplication, such as a multiply-by-two frequency multiplication or multiply-by-four frequency multiplication (dependent upon the required frequency).

A divide-by-three frequency divider is described in ‘RF Local Oscillator Path for GSM Direct Conversion Transceiver with True 50% Duty Cycle Divide by Three and Active Third Harmonic Cancellation’, written by Rahul Magoon and Alyosha Molnar of Conexant Systems Inc., and published in Radio Frequency Integrated Circuits (RFIC) Symposium, 2002 IEEE, and which is incorporated in its entirety herein by reference.

FIG. 1 illustrates a simplified block diagram of an example of such a divide-by-three frequency divider architecture 100. The divide-by-three frequency divider architecture 100 illustrated in FIG. 1 comprises three phase switchable flip-flops 110 operably coupled in a ring arrangement in which a phase input (θ) 120 of each phase switchable flip-flop 110 is dynamically driven by the output 130, or inverse output 135, of the next sequential phase switchable flip-flop 110 in the ring. In this manner, the outputs can be made to transition on either a rising or a falling edge, dependent upon the state of the other flip-flops 110 in the ring. Each flip-flop's output 130 drives the input 140 of the next flip-flop 110, with an inversion in the feedback 150 from the last flip-flop 110 to the first flip-flop 110. Table 1 below illustrates a truth table for the phase switchable flip-flops 110:

TABLE 1
Truth Table for Phase Switchable Flip-Flop

| D | θ | CLK | Q |
|---|---|---|---|
| 0 | 0 | 0 | 0 |
| 0 | 0 | 1 | Hold |
| 0 | 1 | 0 | Hold |
| 0 | 1 | 1 | 0 |
| 1 | 0 | 0 | 1 |
| 1 | 0 | 1 | Hold |
| 1 | 1 | 0 | Hold |
| 1 | 1 | 1 | 1 |

In this conventional divide-by-three frequency divider architecture 100 illustrated in FIG. 1, if a flip-flop 110 clocks in a high signal on a positive edge, once that signal has been passed on to the next flip-flop, it will start clocking on the negative edge of the clock, and vice versa. Advantageously, this ability to transition on both rising and falling edges of the input enables a 50% output duty cycle to be achieved, thereby enabling a low even order harmonic content.

FIG. 2 illustrates a simplified circuit diagram of a conventional implementation of a phase switchable flip-flop 110. In this conventional implementation, the phase switchable flip-flop 110 is implemented using emitter-coupled logic (ECL), which enables a symmetrical design that comprises a fully differential topology in which all signals (inverted and not) propagate with the same delay. The phase switchable flip-flop 110 comprises a substantially standard ECL level triggered D flip-flop, which comprises a cross-coupled bistable memory stage 210 and a clock input stage 220. The phase switchable flip-flop 110 further comprises a phase switching stage 240.

The bistable memory stage 210 comprises two cross-coupled ECL transistor pairs 212, 214; the first ECL transistor pair 212 being arranged to read or ‘capture’ an input value D when an input clock signal (Clk) comprises a first state, and the second ECL transistor pair 214 being arranged to latch the captured value when the input clock signal (Clk) comprises the first state. The clock input stage 220 comprises two transistors 222, 224 operably coupled between the ECL transistor pairs 212, 214 and a low voltage supply rail (Vss) 230. Each transistor 222, 224 of the clock input stage 220 is arranged to selectively couple an ECL transistor pair 212, 214 to the low voltage supply rail (Vss) 230 in accordance with the received clock signal (Clk). In particular in FIG. 2, a first transistor 222 of the clock input stage 220 is arranged to selectively couple an ECL transistor pair 212, 214 to the low voltage supply rail (Vss) 230 when the input clock signal (Clk) comprises a ‘high’ state, whilst a second transistor 224 of the clock input stage 220 is arranged to selectively couple an ECL transistor pair 212, 214 to the low voltage supply rail (Vss) 230 when the input clock signal (Clk) comprises a ‘low’ state.

The phase switching stage 240 comprises an extra set of switching transistor pairs 242, 244, and is provided between the bistable memory stage 210 and the clock input stage 220, which enables phase inversions to be accomplished by swapping the signals between the bistable memory stage 210 and the clock input stage 220. Specifically, the switching pairs 242, 244 of the phase switching stage 240 are arranged to enable the transistors 222, 224 of the clock input stage 220 to which the outputs of the ECL transistor pairs 212, 214 of the bistable memory stage 210 are coupled to be swapped in accordance with a phase input signal (θ). In this manner, the clock state upon which the respective ECL transistor pairs 212, 214 of the bistable memory stage 210 are operably coupled to the low voltage supply rail (Vss) 230 may be switched in accordance with the phase input signal (θ), thereby enabling a phase inversion of the flip-flop circuit 110.

Modern RF transceiver designs are required to operate within a low voltage (e.g. 3.3V) architecture, utilising frequency dividers featuring a 50% duty cycle in order to achieve low even order harmonic content. One problem with the conventional implementation of a phase switchable flip-flop 110 illustrated in FIG. 2 is that the bistable memory stage 210, phase switching stage 240 and clock input stage 220 are stacked one on top of the other between the voltage supply rails 230, 235. Accordingly, a large supply voltage is required to bias each of the active devices (i.e. transistors in the illustrated example), which in a low voltage architecture typically results in little, if any, voltage headroom. Accordingly, such a conventional implementation of a phase switchable flip-flop 110 illustrated in FIG. 2 makes low voltage transceiver design difficult due to its large supply voltage requirements.

### SUMMARY OF THE INVENTION

The present invention provides a phase switchable bistable memory device, and a frequency divider and a radio frequency transceiver comprising such a phase switchable bistable memory device as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 illustrates a simplified block diagram of such an example of a divide-by-three frequency divider architecture.

FIG. 2 illustrates a simplified circuit diagram of a conventional implementation of a phase switchable flip-flop.

FIG. 3 illustrates a simplified circuit diagram of an example of a phase switchable bistable memory device.

FIG. 4 illustrates a simplified circuit diagram of an alternative example of a phase switchable bistable memory device.

FIG. 5 illustrates a simplified example of a radio frequency transceiver.

### DETAILED DESCRIPTION

The present invention will now be described with reference to a phase switchable flip-flop device adapted for use within, for example, a divide-by-three frequency divider for a local oscillator (LO) signal path of a radio frequency (RF) transceiver. Some examples of the invention separate out the phase-switching component from the bistable memory component, thereby providing more headroom for active devices. In some examples, this separation of functional components may offer better functionality for a frequency divider for higher frequency applications.

However, it will be appreciated that the present invention is not limited to such an implementation, and examples of the present invention may be equally implemented within other devices requiring a phase switchable bistable memory device, and in particular within low voltage (e.g. 3.3V) architectures.

Furthermore, because the illustrated embodiments of the present invention may, for the most part, be implemented using electronic components and circuits known to those skilled in the art, details will not be explained in any greater extent than that considered necessary as illustrated below, for the understanding and appreciation of the underlying concepts of the present invention and in order not to obfuscate or distract from the teachings of the present invention.

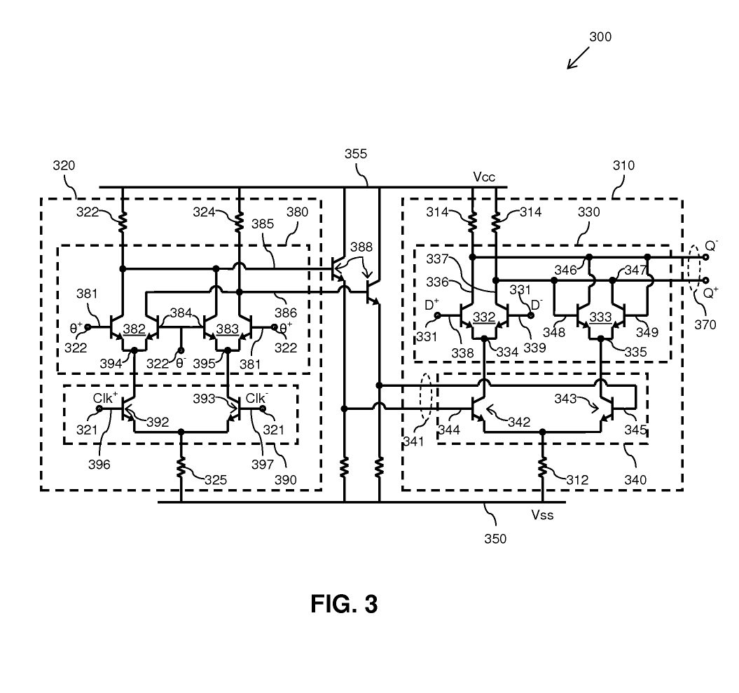

Referring first to FIG. 3, there is illustrated a simplified circuit diagram of an example of a phase switchable bistable memory device 300, such as may be implemented within an integrated circuit device comprising at least one die within a single integrated circuit package. In the illustrated example, the phase switchable bistable memory device 300 comprises a differential, phase switchable flip-flop, and comprises a bistable memory component 310 and a phase switching component 320. In the illustrated example, the bistable memory component is implemented by way of emitter coupled logic (ECL), and comprises a bistable memory stage 330 and a state transition stage 340. The bistable memory stage is arranged to receive an input signal, which in the illustrated example comprises a differential input signal (D) 331. The state transition stage 340 is arranged to receive a state transition signal, which in the illustrated example comprises a differential state transition signal 341, and to cause the bistable memory stage 330 to capture a logical state of the received input signal 331 upon a transition from a first logical state of the state transition signal 341 to a second logical state of the state transition signal 341.

For example, the bistable memory stage 330 of the bistable memory component 310 illustrated in FIG. 3 comprises two cross-coupled switching element pairs 332, 333, which in the illustrated example comprise cross-coupled bipolar junction transistor pairs. Base terminals 338, 339 of the first of the cross-coupled switching element pairs 332 of the bistable memory stage 330 are arranged to receive the differential components of the input signal 331. In this manner, when the differential input signal 331 comprises a first, ‘high’ logical state, such that a high voltage level is received at a first base terminal 338 of the first of the cross-coupled switching element pairs 332 and a low voltage level is received at a second base terminal 339 of the first of the cross-coupled switching element pairs 332, a first switching element of the first of the cross-coupled switching element pairs 332 is biased ‘on’ whilst a second switching element of the first of the cross-coupled switching element pairs 332 is biased ‘off’. Conversely, when the differential input signal 331 comprises a second, ‘low’ logical state, such that a low voltage level is received at the first base terminal 338 of the first of the cross-coupled switching element pairs 332 and a high voltage level is received at the second base terminal 339 of the first of the cross-coupled switching element pairs 332, the first switching element of the first of the cross-coupled switching element pairs 332 is biased ‘off’ whilst the second switching element of the first of the cross-coupled switching element pairs 332 is biased ‘on’.

In contrast, a base terminal 348 and a collector terminal 346 of a first switching element of the second of the cross-coupled switching element pairs 333 of the bistable memory stage 330 are coupled to the positive component and the negative component respectively of the differential output 370. Conversely, a base terminal 349 and a collector terminal 347 of a second switching element of the second of the cross-coupled switching element pairs 333 of the bistable memory stage 330 are coupled to the negative component and the positive component respectively of the differential output 370.

The state transition stage 340 of the bistable memory component 310 illustrated in FIG. 3 comprises two switching elements 342, 343, for example also comprising bipolar junction transistors, operably coupled between the bistable memory stage 330 and a low voltage supply rail (Vss) 350. Each of the switching elements 342, 343 of the state transition stage 340 is arranged to selectively couple (via resistance 312) a common emitter output 334, 335 of a respective cross-coupled switching element pair 332, 333 to the low voltage supply rail (Vss) 350 (via resistance 312) in accordance with the differential state transition signal 341.

In this manner, when the differential state transition signal 341 comprises a first, ‘high’ logical state, such that a high voltage level is received at a base terminal 344 of the first switching element 342 of the state transition stage 340 and a low voltage level is received at a base terminal 345 of the second switching element 343 of the state transition stage 340, the first switching element 342 is biased ‘on’ whilst the second switching element 343 is biased ‘off’. As such, when the differential state transition signal 341 comprises a high logical state, the first switching element 342 operably couples the first of the cross-coupled switching element pairs 332 of the bistable memory stage 330 to the low voltage supply rail (Vss) 350. Conversely, when the differential state transition signal 341 comprises a second, ‘low’ logical state, such that a low voltage level is received at the base terminal 344 of the first switching element 342 of the state transition stage 340 and a high voltage level is received at the base terminal 345 of the second switching element 343 of the state transition stage 340, the first switching element 342 is biased ‘off’ whilst the second switching element 343 is biased ‘on’. As such, when the differential state transition signal 341 comprises a low logical state, the second switching element 343 operably couples the second of the cross-coupled switching element pairs 333 of the bistable memory stage 330 to the low voltage supply rail (Vss) 350.

Collector nodes 336, 337 of the first of the cross-coupled switching element pairs 332 of the bistable memory stage 330 are operably coupled to a high voltage supply rail (Vcc) 355 via resistances 314. In this manner, when the first switching element 342 of the state transition stage 340 is biased ‘on’ such that the common emitter output 334 of the first cross-coupled switching element pair 332 is operably coupled to ground, a positive component of a differential output 370 of the bistable memory stage 330, which is operably coupled to the collector node 337, will be pulled to an opposite voltage level to that of the negative component of the differential input signal 331, whilst a negative component of the differential output 370 of the bistable memory stage 330, which is operably coupled to the collector node 336, will be pulled to an opposite voltage level to that of the positive component of the differential input signal 331. In this manner, whilst the differential state transition signal 341 comprises a high logical state such that the first switching element 342 of the state transition stage 340 is biased ‘on’, the differential output 370 of the bistable memory stage 330 comprises a logical stage corresponding to that of the differential input signal 331.

However, when the differential state transition signal 342 transitions from a high logical state to a low logical state such that the first switching element 342 of the state transition stage 340 is biased ‘off’, the first cross-coupled switching element pair 332 of the bistable memory stage 330 is no longer coupled to the low voltage supply rail (Vss) 350. As a result, the collector nodes 336, 337 thereof, and thus the differential output 370 of the bistable memory stage 330, are no longer influenced by the differential input signal 331. Accordingly, the logical state of the differential input signal 331 is effectively ‘captured’ by the first cross-coupled switching element pair 332 of the bistable memory stage 330 upon a transition of the differential state transition signal 342 from a high logical state to a low logical state.

Furthermore, when the differential state transition signal 342 is in a low logical state such that the second switching element 343 of the state transition stage 340 is biased ‘on’, the common emitter output 335 of the second cross-coupled switching element pair 333 is operably coupled to the low voltage supply rail (Vss) 350. Accordingly, the switching elements of the second cross-coupled switching element pair latch the logical states of the positive and negative components of the differential output 370. Accordingly, the captured logical state of the differential input signal 331 is latched by the second cross-coupled switching element pair 333 of the bistable memory stage 330 whilst the differential state transition signal 342 comprises a low logical state.

The phase switching component 320 is arranged to receive a clock input signal and a phase control signal, which in the illustrated example comprise a differential clock input signal 321 and a differential phase control signal 322 respectively. The phase switching component 320 is further arranged to output a state transition signal comprising transitions between logical states corresponding to transitions between logical states of the clock input signal 321 and comprising a phase relative to the clock input signal 321 based on the received phase control signal 322. The state transition signal output by the phase switching component 320 is then provided to the state transition stage 340 of the bistable memory component 310. In particular in the example illustrated in FIG. 3, the phase switching component 320 is arranged to output the state transition signal 341 comprising either a phase matching a phase of the clock input signal 321 or a phase inverted relative to the phase of the clock input signal dependent on a logical state of the phase control signal 322.

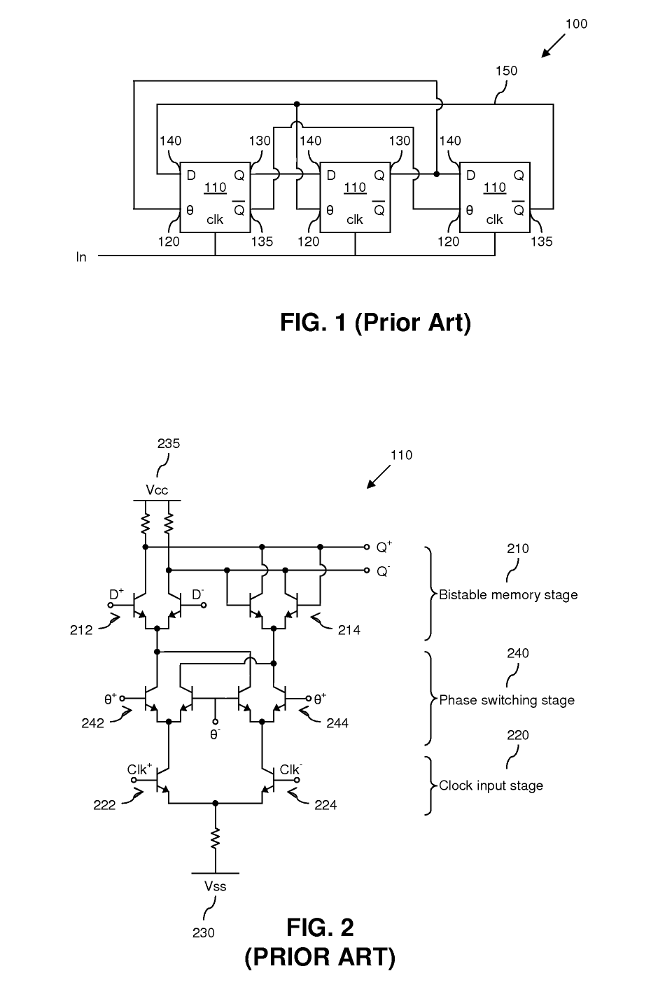

Advantageously, by separating out the phase switching component 320 from the bistable memory component 310 in this manner, for example by operably coupling the phase switching component 320 in parallel with the bistable memory component 310 between the voltage supply rails 350, 355 as illustrated in FIG. 3, fewer active elements (e.g. transistors in the illustrated example) are stacked between the supply rails compared with the conventional prior art arrangement illustrated in FIG. 2. Accordingly, a smaller supply voltage across the phase switchable bistable memory device is required, thereby making the phase switchable bi-stable memory device 300 illustrated in FIG. 3 more suitable for low voltage applications, such as being used within a frequency divider for a local oscillator (LO) signal path of a radio frequency (RF) transceiver, for example the divide-by-three frequency divider arrangement illustrated in FIG. 1.

In the example illustrated in FIG. 3, the phase switching component 320 comprises an eXclusive OR (XOR) gate based on a standard Gilbert cell. As such, the phase switching component 320 comprises a clock input stage 390 arranged to receive a clock input signal and to drive the state transition signal 341 in accordance with the received clock signal, and a phase switching stage 380 operably coupled between the clock input stage 390 and the bistable memory component and arranged to receive a phase control signal and to configure a phase of the state transition signal in accordance with the phase control signal.

The phase switching stage 380 of the phase switching component 320 illustrated in FIG. 3 comprises two emitter coupled transistor pairs 382, 383, which in the illustrated example comprise emitter coupled bipolar junction transistor pairs. Base terminals 381 of a first transistor of each of the emitter coupled transistor pairs 382, 383 are arranged to receive a positive component of the differential phase control signal 322, whilst base terminals 384 of a second transistor of each of the emitter coupled transistor pairs 382, 383 are arranged to receive a negative component of the differential phase control signal 322. In this manner, when the differential phase control signal 322 comprises a first, ‘high’ logical state, such that a high voltage level is received at the base terminals 381 of the first transistor of each of the emitter coupled transistor pairs 382, 383 and a low voltage level is received at the base terminals 384 of the second transistor of each of the emitter coupled transistor pairs 382, 383, the first transistor of each of the emitter coupled transistor pairs 382, 383 is biased ‘on’ whilst the second transistor of each of the emitter coupled transistor pairs 382, 383 is biased ‘off’. Conversely, when the differential phase control signal 322 comprises a first, ‘low’ logical state, such that a low voltage level is received at the base terminals 381 of the first transistor of each of the emitter coupled transistor pairs 382, 383 and a high voltage level is received at the base terminals 384 of the second transistor of each of the emitter coupled transistor pairs 382, 383, the first transistor of each of the emitter coupled transistor pairs 382, 383 is biased ‘off’ whilst the second transistor of each of the emitter coupled transistor pairs 382, 383 is biased ‘on’.

A collector terminal of the first transistor of the first emitter coupled transistor pair 382 and a collector terminal of the second transistor of the second emitter coupled transistor pair 383 are operably coupled to a first state transition output node 385, which in turn is operably coupled to the positive voltage supply rail 355 via resistance 323, and arranged to output a negative component of the differential state transition signal 341. Conversely, a collector terminal of the second transistor of the first emitter coupled transistor pair and a collector terminal of the first emitter coupled transistor pair 383 are operably coupled to a second state transition node 386, which in turn is operably coupled to the positive voltage rail 355 via resistance 324, and arranged to output a positive component of the differential state transition signal 341.

The clock input stage 390 of the phase switching component 320 illustrated in FIG. 3 comprises two switching elements 392, 393, for example also comprising bipolar junction transistors, operably coupled between the phase switching stage 380 and the low voltage supply rail (Vss) 350. Each of the switching elements 392, 393 of the clock input stage 390 is arranged to selectively couple (via resistance 325) a common emitter output 394, 395 of a respective emitter coupled transistor pair 382, 383 to the low voltage supply rail (Vss) 350 (via resistance 325) in accordance with the differential clock input signal 321.

In this manner, when the differential clock signal 321 comprises a first, ‘high’ logical state, such that a high voltage level is received at a base terminal 396 of the first switching element 392 of the clock input stage 390 and a low voltage level is received at a base terminal 397 of the second switching element 393 of the clock input stage 390, the first switching element 392 is biased ‘on’ whilst the second switching element 393 is biased ‘off’. As such, when the differential clock input signal 321 comprises a high logical state, the first switching element 392 operably couples the first of the emitter-coupled transistor pairs 382 of the phase switching stage 380 to the low voltage supply rail (Vss) 350. Conversely, when the differential clock input signal 321 comprises a second, ‘low’ logical state, such that a low voltage level is received at the base terminal 396 of the first switching element 392 of the clock input stage 390 and a high voltage level is received at the base terminal 397 of the second switching element 393 of the clock input stage 390, the first switching element 392 is biased ‘off’ whilst the second switching element 393 is biased ‘on’. As such, when the differential clock input signal 321 comprises a low logical state, the second switching element 393 operably couples the second of the emitter-coupled transistor pairs 383 of the phase switching stage 380 to the low voltage supply rail (Vss) 350.

When the differential phase control signal comprises, say, a low logical state, the second transistor of each of the emitter coupled transistor pairs 382, 383 is biased ‘on’. As such, the second switching element 392 of the clock input stage 390 is operably coupled to the second state transition node 386 via the second transistor of the first emitter coupled transistor pair 382. Conversely, the second switching element 393 of the clock input stage 390 is operably coupled to the first state transition node 385 via the second transistor of the second emitter coupled transistor pair 383. In this manner, a differential state transition signal 341 will be output comprising a logical state matching that of the differential clock input signal 321. Accordingly, the differential state transition signal 341 will comprise a phase substantially matching that of the differential clock input signal 321.

Conversely, when the differential phase control signal comprises a high logical state, the first transistor of each of the emitter coupled transistor pairs 382, 383 is biased ‘on’. As such, the first switching element 392 of the clock input stage 390 is operably coupled to the first state transition node 385 via the first transistor of the first emitter coupled transistor pair 382. Conversely, the second switching element 393 of the clock input stage 390 is operably coupled to the second state transition node 386 via the first transistor of the second emitter coupled transistor pair 383. In this manner, a differential state transition signal 341 will be output comprising an inverse logical state to that of the differential clock input signal 321. Accordingly, the differential state transition signal 341 will comprise a substantially inverse phase relative to that of the differential clock input signal 321.

Thus, in this manner, the emitter coupled transistor pairs 382, 383 of the phase switching stage 380 are arranged to enable the differential components of the state transition signal 341 driven by the clock input stage 390 to be swapped in accordance with the phase control signal.

In the illustrated example, the phase switchable bistable memory device 300 further comprises an emitter follower 388 operably coupled between each of the first and second state transition output nodes 385, 386 and the base terminals 344, 345 of the switching elements 342, 343 of the state transition stage 340 respectively. In this manner, the emitter followers 388 are able to drive the differential state transition signal 341, and shift the voltage levels of the differential state transition signal 341 so that they are compatible with the required voltage levels for the base terminals 344, 345 of the switching elements 342, 343 of the state transition stage 340.

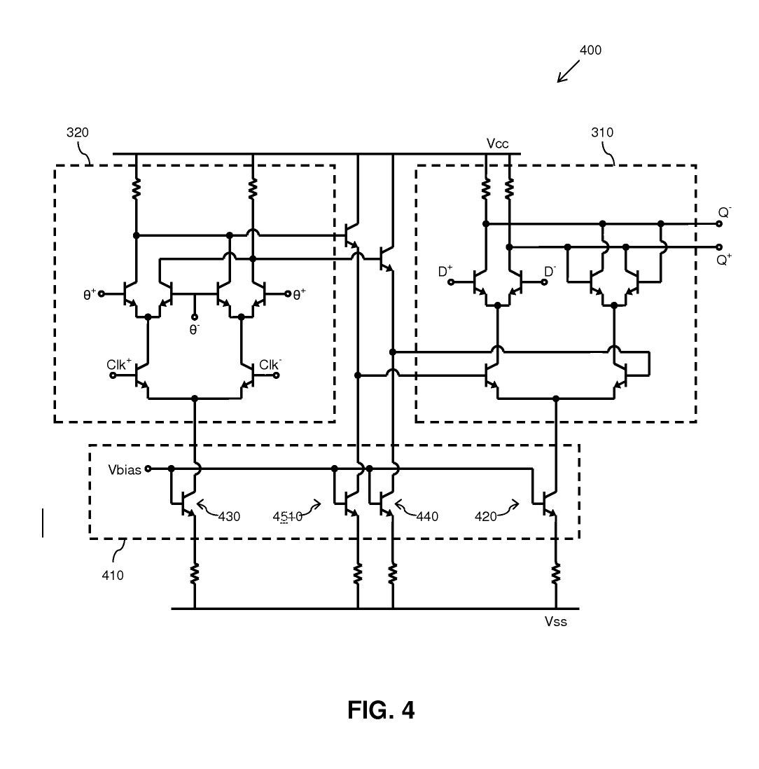

Referring now to FIG. 4, there is illustrated a simplified circuit diagram of an alternative example of a phase switchable bistable memory device 400. The phase switchable bistable memory device 400 of FIG. 4 comprises substantially the same bistable memory component 310 and phase switching component 320 as for the example illustrated in FIG. 3. Advantageously, and as mentioned above, by separating out the phase switching component 320 from the bistable memory component 310, for example by operably coupling the phase switching component 320 in parallel with the bistable memory component 310 between the voltage supply rails 350, 355 as illustrated in FIG. 3 and FIG. 4, fewer active elements (e.g. transistors in the illustrated example) are stacked between the supply rails compared with the conventional prior art arrangement illustrated in FIG. 2. Accordingly, a smaller supply voltage across the phase switchable bistable memory device 400 is required, providing greater voltage headroom within a low voltage application. Accordingly, in the example illustrated in FIG. 4, the additional voltage headroom afforded by the arrangement of the bistable memory component 310 and phase switching component 320 is made use of to enable a current mirror component 410 to be implemented within the phase switchable bistable device 400. Specifically, in the illustrated example, the current mirror component 410 comprises a first current mirror element 420 operably coupled between the state transition stage 340 of the bistable memory component 310 and the low voltage supply rail (Vss) 350. The current mirror component 410 of the illustrated example further comprises a second current mirror element 430 operably coupled between the clock input stage 390 of the phase switching component 320 and the low voltage supply rail (Vss) 350. The current mirror component 410 of the illustrated example still further comprises current mirror elements 440, 450 operably coupled between each of the emitter followers 388 and the low voltage supply rail (Vss) 350.

Advantageously, the inclusion of the current mirror component 410 provides stabilization to the performance of the phase switching bistable memory device 400 over changes in temperature, and helps to reduce ‘spikes’ and ‘glitches’ in the differential output signal.

A consideration for the examples of phase switchable bistable memory devices illustrated in FIGS. 3 and 4 is that, since a frequency divider is typically used in the low frequency part of a local oscillator chain due to their complexity, the maximal operating frequency is reduced. Therefore, additional current is needed by the phase switching component 320 working at a low frequency range. However, such additional current is typically negligible (e.g. less than 1 mA) with regard the total current consumption of the complete local oscillator chain. In return for such negligibly higher current consumption, by separating out the phase switching component from the bi-stable memory component, more headroom for active devices is created, enabling a higher maximal operating speed of the phase switchable bistable memory devices illustrated in FIGS. 3 and 4 compared with the conventional prior art architecture illustrated in FIG. 2.

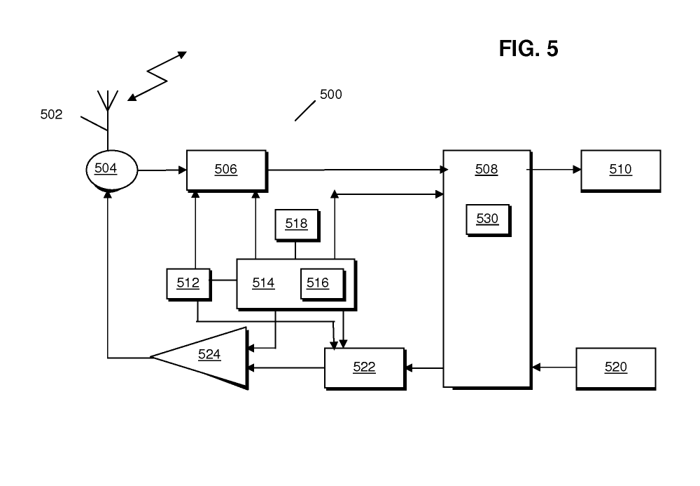

Referring first to FIG. 5, a block diagram of a radio frequency (RF) transceiver 500, for example in a context of a wireless communication unit (sometimes referred to as a mobile subscriber unit (MS) or a user equipment (UE)) is shown, in accordance with a preferred embodiment of the invention. The RF transceiver 500 contains an antenna 502 preferably coupled to a duplex filter or antenna switch 504 that provides isolation between receive and transmit chains within the RF transceiver 500.

The receiver chain, as known in the art, includes receiver front-end circuitry 506 (effectively providing reception, filtering and intermediate or base-band frequency conversion). A local oscillator circuit 512 is operably coupled to the receiver front-end circuitry 506 and arranged to provide a radio frequency signal to support mixing and frequency translation with the receiver front-end circuitry 506.

The receiver front-end circuitry 506 is serially coupled to a signal processing function 508. An output from the signal processing function 508 is provided to a suitable output device 510, such as a screen or flat panel display. A controller 514 maintains overall control of the radio frequency transceiver 500. The controller 514 is also coupled to the receiver front-end circuitry 506 and the signal processing function 508 (generally realised by a digital signal processor (DSP)). The controller is also coupled to a memory device 516 that selectively stores operating regimes, such as decoding/encoding functions, LO settings, and the like. Furthermore, a timer 518 is operably coupled to the controller 514 to control the timing of operations (transmission or reception of time-dependent signals) within the radio frequency transceiver 500.

As regards the transmit chain, this essentially includes an input device 520, such as a keypad, coupled in series through transmitter/modulation circuitry 522 and a power amplifier 524 to the antenna 502. The transmitter/modulation circuitry 522 and the power amplifier 524 are operationally responsive to the controller 514. The local oscillator circuit 512 is operably coupled to the transmitter/modulation circuitry 522 and arranged to provide a radio frequency signal to support mixing and frequency translation with the transmitter/modulation circuitry 522. In some examples, the LO circuit 512 has been adapted to comprise a phase switchable flip-flop device, as hereinbefore described, adapted for use within, for example, a divide-by-three frequency divider for a local oscillator (LO) signal path of the RF transceiver 500.

The signal processor function 508 in the transmit chain may be implemented as distinct from the processor in the receive chain. Alternatively, a single processor 508 may be used to implement processing of both transmit and receive signals, as shown in FIG. 5. Clearly, the various components within the radio frequency transceiver 500 can be realised in discrete or integrated component form, with an ultimate structure therefore being merely an application-specific or design selection.

In the foregoing specification, the invention has been described with reference to specific examples of embodiments of the invention. It will, however, be evident that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will be appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms ‘assert’ or ‘set’ and ‘negate’ (or ‘de-assert’ or ‘clear’) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Any arrangement of components to achieve the same functionality is effectively ‘associated’ such that the desired functionality is achieved. Hence, any two components herein combined to achieve a particular functionality can be seen as ‘associated with’ each other such that the desired functionality is achieved, irrespective of architectures or intermediary components. Likewise, any two components so associated can also be viewed as being ‘operably connected’, or ‘operably coupled’, to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms ‘a’ or ‘an’, as used herein, are defined as one or more than one. Also, the use of introductory phrases such as ‘at least one’ and ‘one or more’ in the claims should not be construed to imply that the introduction of another claim element by the indefinite articles ‘a’ or ‘an’ limits any particular claim containing such introduced claim element to inventions containing only one such element, even when the same claim includes the introductory phrases ‘one or more’ or ‘at least one’ and indefinite articles such as ‘a’ or ‘an’. The same holds true for the use of definite articles. Unless stated otherwise, terms such as ‘first’ and ‘second’ are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. A phase switchable bistable memory device comprising:
a bistable memory component and a phase switching component, the bistable memory component comprises:
a bistable memory stage arranged to receive an input signal; and
a state transition stage arranged to receive a state transition signal and to cause the bistable memory stage to capture a logical state of the received input signal upon a transition from a first logical state of the state transition signal to a second logical state of the state transition signal;
wherein the phase switching component is arranged to receive a clock input signal and a phase control signal, and to output the state transition signal comprising transitions between logical states corresponding to transitions between logical states of the clock input signal and comprising a phase relative to the clock input signal based at least partly on the received phase control signal.

2. The phase switchable bistable memory device of claim 1, wherein the phase switching component is arranged to output a state transition signal comprising one of:
a phase that matches a phase of the clock input signal; and
a phase inverted relative to a phase of the clock input signal,
dependent upon a logical state of the phase control signal.

3. The phase switchable bistable memory device of claim 1 wherein the bistable memory component and the phase switching component are operably coupled in parallel between voltages supply rails.

4. The phase switchable bistable memory device of claim 1, wherein the phase switching component comprises a clock input stage arranged to receive the clock input signal and to drive the state transition signal in accordance with the received clock signal.

5. The phase switchable bistable memory device of claim 4 further comprising a phase switching stage operably coupled between the clock input stage and the bistable memory component, and arranged to receive the phase control signal and to configure a phase of the state transition signal in accordance with the phase control signal.

6. The phase switchable bistable memory device of claim 5, wherein the phase switching stage comprises a set of emitter coupled transistor pairs arranged to enable differential components of the state transition signal driven by the clock input stage to be swapped in accordance with the phase control signal.

7. The phase switchable bistable memory device of claim 1, wherein the phase switchable bistable memory device comprises a differential topology.

8. The phase switchable bistable memory device of claim 1, wherein the bistable memory stage of the bistable memory component comprises two cross-coupled switching element pairs; a first of the cross-coupled switching element pairs being arranged to capture a logical state of a differential input signal upon a transition from a first logical state of the state transition signal to a second logical state of the state transition signal, and the second of the cross-coupled switching element pairs being arranged to latch a logical state captured by the first of the cross-coupled switching element pairs when the state transition signal comprises the first logical state.

9. The phase switchable bistable memory device of claim 8, wherein the state transition stage of the bistable memory component comprises two switching elements operably coupled between the bistable memory stage and a low voltage supply rail, such that each switching element is arranged to selectively couple a respective cross-coupled switching element pair of the bistable memory stage to the low voltage supply rail in accordance with a respective component of the differential state transition signal.

10. The phase switchable bistable memory device of claim 1, wherein the phase switchable bistable memory device comprises emitter coupled logic.

11. The phase switchable bistable memory device of claim 1, wherein the phase switchable bistable memory device further comprises an emitter follower operably coupled between each output of the phase switching component and each respective input of the state transition stage of the bistable memory component.

12. The phase switchable bistable memory device of claim 1, wherein the bistable memory component comprises a flip-flop.

13. The phase switchable bistable memory device of claim 1, wherein the phase switching stage comprises an eXclusive OR gate.

14. The phase switchable bistable memory device of claim 1, wherein the phase switchable bistable memory device further comprises a current mirror component comprising at least one current mirror circuit operably coupled between the bistable memory component and a voltage supply rail.

15. The phase switchable bistable memory device of claim 14, wherein the current mirror component further comprises at least one current mirror circuit operably coupled between the phase switching component and the voltage supply rail.

16. The phase switchable bistable memory device of claim 1, when implemented within an integrated circuit device comprising at least one die within a single integrated circuit package.

17. A frequency divider comprising at least one phase switchable bistable memory device according to claim 1.

18. The frequency divider of claim 17, wherein the frequency divider comprises a divide-by-three frequency divider.

19. A radio frequency (RF) transceiver comprising at least one frequency divider according to claim 17.

20. A radio frequency (RF) transceiver of claim 19, wherein the phase switching component comprises a clock input stage arranged to receive the clock input signal and to drive the state transition signal in accordance with the received clock signal.
